(19) United States
(12) Patent Application Publication
(10) Pub. No.: US 2017/0133571 A1
(43) Pub. Date: May 11, 2017

(54) ENERGY HARVESTING DEVICE

(71) Applicant: KABUSHIKI KAISHA TOSHIBA, Tokyo (JP)

(72) Inventors: Takeshi UENO, Kawasaki Kanagawa (JP); Toshiyuki UMEDA, Inagi Tokyo (JP); Hideo KASAMI, Yokohama Kanagawa (JP)

(73) Assignee: KABUSHIKI KAISHA TOSHIBA, Tokyo (JP)

(21) Appl. No.: 15/259,925

(22) Filed: Sep. 8, 2016

(30) Foreign Application Priority Data
Nov. 10, 2015 (JP) 2015-220530

(51) Int. Cl. H01L 35/32; H02N 2/18

(52) U.S. Cl. CPC H01L 35/32; H02N 2/18

(57) ABSTRACT

In order to make possible to perform thermoelectric generation utilizing a thermal source placed outside a housing case, according to one embodiment, an energy harvesting device is provided. The energy harvesting device includes: a housing case; and a thermoelectric generation element arranged to contact with an outer surface of the housing case.

### CROSS-REFERENCE TO RELATED APPLICATIONS

This application is based upon and claims the benefit of priority from Japanese Patent Application No. 2015-220530, filed on Nov. 10, 2015; the entire contents of which are incorporated herein by reference.

### FIELD

Embodiments of the present invention relates to an energy harvesting device.

### BACKGROUND

Recently energy harvesting that obtains electric power from a weak energy source in the environment has been under focus. Thermoelectric generation is known as one method for the energy harvesting.

Conventionally, there has been proposed an energy harvesting device utilizing the thermoelectric generation, which includes a housing case, a thermoelectric generation element arranged inside the housing case and a thermal source arranged inside the housing case. In this energy harvesting device, the thermoelectric generation element is arranged in such a manner that one end makes contact with the thermal source and the other end makes contact with an inner surface of the housing case. With this configuration, the one end of the thermoelectric generation element is heated by the thermal source and the other end is cooled by the housing case. As a result, a difference in temperature between both the ends of the thermoelectric generation element is generated to perform the thermoelectric generation.

However, according to the conventional energy harvesting device, since the thermoelectric generation element is arranged inside the housing case, it is not possible to perform the thermoelectric generation utilizing the thermal source placed outside the housing case.

### BRIEF DESCRIPTION OF THE DRAWINGS

FIG. 1 is a diagram showing an example of an energy harvesting device according to a first embodiment;

FIG. 2 is a diagram showing another example of the energy harvesting device according to the first embodiment;

FIG. 3 is a diagram showing an example of an energy harvesting device according to a second embodiment;

FIG. 4 is a diagram showing another example of the energy harvesting device according to the second embodiment;

FIG. 5 is a diagram showing a further other example of the energy harvesting device according to the second embodiment;

FIG. 6 is a diagram showing an example of an energy harvesting device according to a third embodiment;

FIG. 7 is a diagram showing another example of the energy harvesting device according to the third embodiment; and

FIG. 8 is a diagram showing a further other example of the energy harvesting device according to the third embodiment.

### DETAILED DESCRIPTION

According to one embodiment, an energy harvesting device includes: a housing case; and a thermoelectric generation element arranged to contact with an outer surface of the housing case. Hereinafter, embodiments of the present invention will be described with reference to the drawings.

### First Embodiment

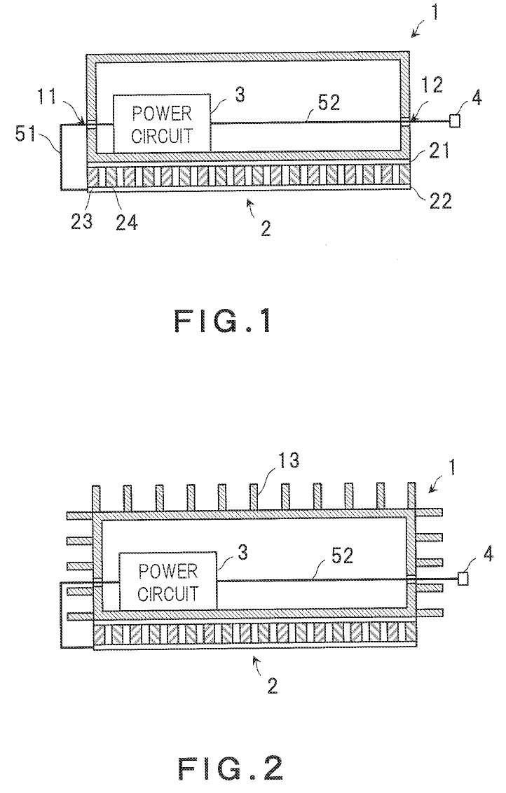

An energy harvesting device according to a first embodiment will be explained with reference to FIG. 1 and FIG. 2. FIG. 1 is a diagram showing an example of the energy harvesting device according to the present embodiment. The energy harvesting device in FIG. 1 is provided with a housing case 1, a thermoelectric generation element 2, a power circuit 3, an output terminal 4 and wires 51, 52.

The housing case 1 is a package that can accommodate therein an electric device such as the power circuit 3. The housing case 1 acts as a heat sink for cooling one surface of the thermoelectric generation element 2. Therefore, the housing case 1 is preferably formed of a material having a high coefficient of thermal conductivity. Specifically, the housing case 1 is preferably formed of metal such as aluminum.

In addition, the housing case 1 has wire holes. The wire holes are through holes provided in the housing case 1 for the passing of the wires. Providing the wire holes enables the electric device inside the housing case 1 and a device outside the housing case 1 (hereinafter, referred to as “external device”) to be connected by wires.

In the example in FIG. 1, the housing case 1 has two wire holes 11, 12. The wire hole 11 is a through hole for the passing of the wire 51. The wire hole 12 is a through hole for the passing of the wire 52.

It should be noted that in the example in FIG. 1, both the wire holes 11, 12 are provided on lateral surfaces of the housing case 1, but may be provided on an upper surface or a lower surface of the housing case 1.

In addition, the housing case 1 may be provided with three wire holes or more, and as shown in FIG. 6 to be described later, the wire hole 12 may be not provided.

In addition, a space between the wire hole of the housing case 1 and the wire passing through the wire hole may be sealed by a plastic packing or the like. Therefore, an Inside of the housing case 1 can be sealed to improve waterproof properties of the energy harvesting device.

The thermoelectric generation element 2 is a flat plate shaped element performing the thermoelectric generation. The thermoelectric generation element 2, when a difference in temperature between one surface and the other surface thereof is generated, generates a voltage corresponding to the generated temperature difference. The thermoelectric generation element 2 is arranged in such a manner that one surface or the other surface makes contact with an outer surface of the housing case 1. The thermoelectric generation element 2 is provided with insulating material plates 21, 22 and thermoelectric materials 23, 24.

The insulating material plate 21 is a plate-shaped member that configures an upper surface of the thermoelectric generation element 2 and is formed of an insulating material. The Insulating material plate 21 makes contact with a lower surface of the housing case 1. The insulation between the thermoelectric materials 23, 24 and the housing case 1 is established by the insulating material plate 21.

The insulating material plate 22 is a plate-shaped member that configures a lower surface of the thermoelectric generation element 2 and is formed of an insulating material. The insulation between the thermoelectric materials 23, 24 and the housing case 1 is established by the insulating material plate 22.

The thermoelectric material 23 includes a plurality of thermoelectric materials that are arranged in a planar direction of the thermoelectric generation element 2 between the insulating material plate 21 and the insulating material plate 22. The thermoelectric material 23 is formed of, for example, a N-type semiconductor or metal.

The thermoelectric material 24 includes a plurality of thermoelectric materials that are arranged in a planar direction of the thermoelectric generation element 2 between the insulating material plate 21 and the insulating material plate 22. The thermoelectric material 24 is formed of, for example, a P-type semiconductor, or metal different from the thermoelectric material 23.

In the example in FIG. 1, the thermoelectric materials 23 and the thermoelectric materials 24 are alternately arranged. One end (upper surface side) of each of the thermoelectric materials 23 is connected to one end (upper surface side) of the thermoelectric material 24 in the right side (or the left side) of the thermoelectric material 23 by a conductive material (the illustration is omitted) such as metal. In addition, the other end (lower surface side) of each of the thermoelectric materials 23 is connected to the other end (lower surface side) of the thermoelectric material 24 in the left side (or the right side) of the thermoelectric material 23 by a conductive material (the illustration is omitted) such as metal. That is, the plurality of thermoelectric materials 23, 24 are connected in series. The wire 51 is connected to both ends of the thermoelectric materials 23, 24 connected in series.

In a case where a thermal source is placed on the lower surface side of the thermoelectric generation element 2, the lower surface of the thermoelectric generation element 2 is heated by the thermal source. On the other hand, the upper surface of the thermoelectric generation element 2 is heated by the thermal source, and at the same time, is caused to release heat by the housing case 1 thereby being cooled. As a result, a temperature of the upper surface of the thermoelectric generation element 2 becomes lower than a temperature of the lower surface. That is, there is generated a difference in temperature between the upper surface and the lower surface of the thermoelectric generation element 2.

The thermoelectric generation element 2 generates a voltage corresponding to this temperature difference. In a case where the temperature difference is approximately several K, the voltage to be generated amounts to, for example, several 10 mV. The thermoelectric generation element 2 outputs output power corresponding to the generated voltage.

It should be noted that in the example in FIG. 1, the thermoelectric generation element 2 is arranged such that the upper surface makes contact with the lower surface of the housing case 1, but may be arranged such that the upper surface makes contact with the lateral surface or the upper surface of the housing case 1. In addition, the thermoelectric generation element 2 may be arranged such that the lower surface makes contact with the outer surface of the housing case 1.

The wire 51 is a power wire (or power line) for connection between the thermoelectric generation element 2 and the power circuit 3. The wire 51 passes through the wire hole 11 of the housing case 1. The output power of the thermoelectric generation element 2 is input into the power circuit 3 through the wire 51.

The power circuit 3 is arranged inside the housing case 1. The power circuit 3 includes a booster circuit, and boosts the output power of the thermoelectric generation element 2 input through the wire 51 to a desired voltage (for example, approximately several V). The power circuit 3 outputs the output power corresponding to the boosted voltage.

It should be noted that the power circuit 3 may be provided with an electric storage element (battery or capacitor) that stores the output power of the thermoelectric generation element 2. An electric storage element as a material different from the power circuit 3 may be provided inside the housing case 1.

In addition, in the example in FIG. 1, the power circuit 3 is arranged in such a manner as to make contact with the lower surface of the housing case 1, but may be arranged to be spaced from the lower surface by a spacer or the like. With this configuration, heat of the power circuit 3 is difficult to be transferred to the lower surface of the housing case 1, thus making it possible to improve a cooling efficiency of the upper surface of the thermoelectric generation element 2 by the housing case 1. In addition, the power circuit 3 may be arranged on the upper surface or on the lateral surface of the housing case 1.

The wire 52 is a power wire for connection between the power circuit 3 and the output terminal 4. The wire 52 passes through the wire hole 12 of the housing case 1. The output power of the power circuit 3 is output from the output terminal 4 through the wire 52.

The output terminal 4 is a terminal connectable to a power supply terminal of an external device. The energy harvesting device according to the present embodiment supplies the output power of the power circuit 3 to the external device through the output terminal 4. The external device can obtain the output power of the power circuit 3 by connecting the output terminal 4 to the power supply terminal.

As described above, the energy harvesting device according to the present embodiment boosts the electric voltage generated by the thermoelectric generation element 2 by the power circuit 3, and supplies the boosted electric voltage to the external device through the output terminal 4. Since the output power of the thermoelectric generation element 2 is boosted by the power circuit 3, the energy harvesting device can supply the output power of an appropriate voltage to the external device.

Since the thermoelectric generation element 2 is provided outside the housing case 1, the thermoelectric generation element 2 can generate electric power by using a thermal source outside the housing case 1.

In addition, since the housing case 1 acts as heat sink for cooling the upper surface (or the lower surface) of the thermoelectric generation element 2, it is not necessary to provide a heat sink exclusive to the thermoelectric generation element 2. Therefore, it is possible to miniaturize the energy harvesting device.

The energy harvesting device according to the present embodiment as explained above can be used as a power source of the sensor, the wireless communication device and the like (hereinafter, referred to as “sensor and the like”) installed near the thermal source. An explanation will be made of a case where the energy harvesting device in FIG. 1 is used as a power source of the sensor and the like installed near an engine, a motor, an exhaust pipe and the like (hereinafter, referred to as “engine and the like”) for an automobile, as an example.

In this case, a user of the energy harvesting device installs the energy harvesting device such that the lower surface of the thermoelectric generation element 2 makes contact with or close contact with the engine and the like as the thermal source. Further, the user installs the sensor and the like to a desired position. In addition, the user connects the output terminal 4 and power supply terminals of the sensor and the like.

As a result, as long as the engine and the like are heated, the electric power is supplied to the sensor and the like from the energy harvesting device, thus making it possible to continue to drive the sensor and the like.

FIG. 2 is a diagram showing another example of the energy harvesting device according to the present embodiment. In the energy harvesting device in FIG. 2, the housing case 1 is provided with heat release fins 13. The heat release fins 13 are provided to project from the outer surface of the housing case 1. The other configuration is identical to that in FIG. 1.

A surface area of the housing case 1 increases by thus providing the heat release fins 13 on the outer surface of the housing case 1. As a result, the heat release efficiency of the housing case 1 improves, thus making it possible to improve a cooling effect of the upper surface of the thermoelectric generation element 2 by the housing case 1.

It should be noted that in the example in FIG. 2, the heat release fins 13 are provided on the lateral surface and the upper surface of the housing case 1, but may be provided on one of the lateral surface or the upper surface. In addition, the heat release fins 13 as a material different from the housing case 1 may be attached to make contact with the outer surface of the housing case 1.

### Second Embodiment

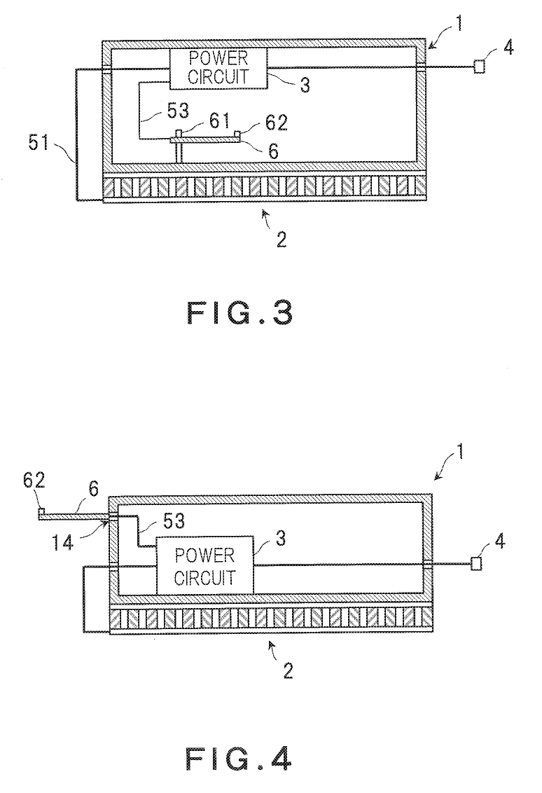

An explanation will be made of an energy harvesting device according to a second embodiment with reference to FIG. 3 to FIG. 5. The energy harvesting device according to the present embodiment utilizes vibration electric generation together with thermoelectric generation. FIG. 3 is a diagram showing an example of the energy harvesting device according to the present embodiment. The energy harvesting device in FIG. 3 is provided with a piezo element 6, a spacer 61, a mass 62 and a wire 53. The other configuration is identical to that in FIG. 1.

The piezo element 6 is a plate-shaped or rod-shaped element that performs vibration electric generation. The piezo element 6 generates a voltage corresponding to an induced strain of the piezo element in the example in FIG. 3, the piezo element 6 is arranged inside the housing case 1.

The spacer 61 is a rod-shaped or plate-shaped member and is fixed at one end to the inner surface of the housing case 1. One end of the piezo element 6 is fixed to the other end of the spacer 61. As a result, the one end of the piezo element 6 is fixed to the housing case 1.

The mass 62 is fixed to the other end of the piezo element 6.

The piezo element 6, the spacer 61 and the mass 62 configure a cantilever beam. When the housing case 1 vibrates, the piezo element 6 vibrates with this vibration. The piezo element 6 generates a voltage corresponding to an induced strain of the piezo element. When the piezo element 6 generates the voltage, the piezo element 6 outputs output power corresponding to the generated voltage. An electric generation amount of the piezo element 6 is maximized when the vibration of the housing case 1 conforms to a resonance frequency of the cantilever beam. The resonance frequency of the cantilever beam is adjustable by the weight of the mass 62.

The wire 53 is a power wire that connects the piezo element 6 and the power circuit 3. The output power of the piezo element 6 is input to the power circuit 3 through the wire 53.

As explained above, in the energy harvesting device according to the present embodiment, the electric power that the thermoelectric generation element 2 generates by the thermoelectric generation and the electric power that the piezo element 6 generates by the vibration electric generation are input to the power circuit 3. In this way, it is possible to increase the electric generation amount of the energy harvesting device by using two kinds of energy harvesting both.

In addition, when the piezo element 6 vibrates, air inside the housing case 1 is stirred to uniform a thermal distribution inside the housing case 1. As a result, the heat release efficiency of the housing case 1 improves, thus making it possible to improve the cooling effect of the upper surface of the thermoelectric generation element 2 by the housing case 1.

In should be noted that in the example in FIG. 3, the energy harvesting device is provided with only one piezo element 6, but may be provided with a plurality of piezo elements 6. In this case, the spacer 61, the mass 62 and the wire 53 may be provided to each of the piezo elements 6.

FIG. 4 is a diagram showing another example of the energy harvesting device according to the present embodiment. In the energy harvesting device in FIG. 4, the piezo element 6 is arranged outside of the housing case 1. Therefore, a wire hole 14 for the passing of the wire 53 is provided in the housing case 1. Since one end of the piezo element 6 is fixed directly to the lateral surface of the housing case 1, the spacer 61 is not provided. The other configuration is identical to that in FIG. 3.

Even the configuration in FIG. 4 can increase the electric generation amount of the energy harvesting device by using the vibration electric generation by the piezo element 6. In addition, since the piezo element 6 acts as a heat release fin, the heat release efficiency of the housing case 1 improves, thus making it possible to improve the cooling effect of the upper surface of the thermoelectric generation element 2 by the housing case 1.

In should be noted that in the example in FIG. 4, the energy harvesting device is provided with only one piezo element 6, but may be provided with a plurality of piezo elements 6. In this case, the mass 62, the wire 53 and the wire hole 14 may be provided to each of the piezo elements 6. The piezo element 6 may be fixed to the other end of the spacer 61 one end of which is fixed on the outer surface of the housing case 1. In addition, the piezo elements 6 each are provided inside and outside the housing case 1.

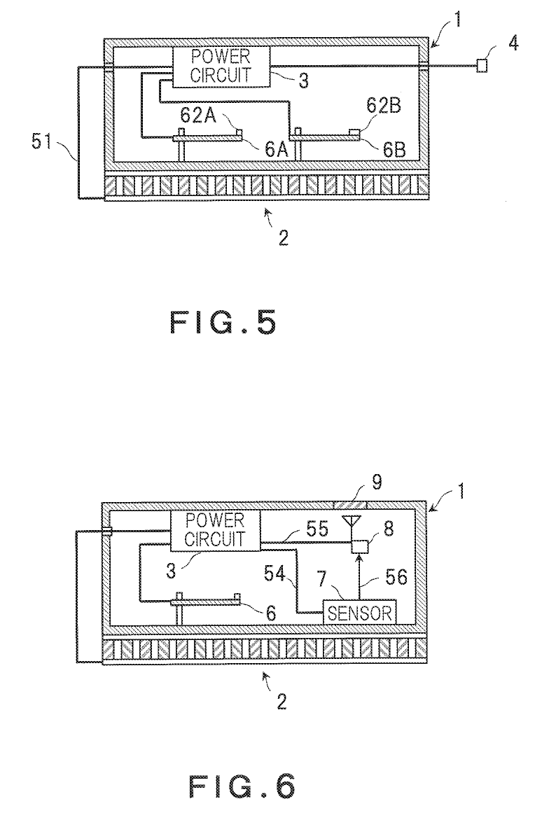

FIG. 5 is a diagram showing a further other example of the energy harvesting device according to the present embodiment. The energy harvesting device in FIG. 5 is provided with two piezo elements 6A, 6B. Masses 62A, 62B differing in weight are respectively fixed on the piezo elements 6A, 6B. The other configuration is identical to that in FIG. 3.

With this configuration, a resonance frequency of the cantilever beam configured by the piezo element 6A and a resonance frequency of the cantilever beam configured by the piezo element 6B become different frequencies. That is, a vibration frequency of the housing case 1 in which the electric generation amount of the piezo element 6A is maximized and a vibration frequency of the housing case 1 in which the electric generation amount of the piezo element 6B is maximized become different frequencies. Therefore, it is possible to widen a vibration frequency band of the housing case 1 in which the energy harvesting device can perform the vibration electric generation.

It should be noted that the energy harvesting device may be provided with three piezo elements 6 or more, wherein the masses 62 each differing in weight are fixed to the respective piezo elements 6.

### Third Embodiment

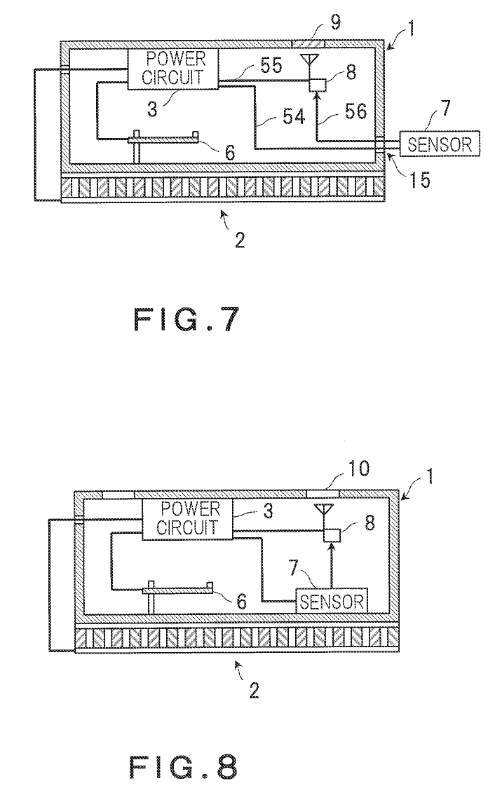

An explanation will be made of an energy harvesting device according to a third embodiment with reference to FIG. 6 and FIG. 7. In each of the aforementioned embodiments, it is assumed that the energy harvesting device is utilized as the power source of the external device. On the other hand, in the present embodiment, an explanation will be made of an energy harvesting device configured to be integral with a sensor, a wireless communication device and the like. FIG. 6 is a diagram showing an example of the energy harvesting device according to the present embodiment. The energy harvesting device in FIG. 6 is provided with a sensor 7, a wireless communication device 8, a radio transmittance portion 9 and wires 54 to 56. Since the sensor and the like are configured to be integral with the housing case 1, the energy harvesting device is not provided with the output terminal 4. The other configuration is identical to that in FIG. 3.

The sensor 7 is arranged inside the housing case 1. The energy harvesting device can mount any sensor such as an acceleration sensor, a temperature sensor, a gas sensor, a magnetic sensor and a pressure sensor, as a sensor. In addition, the energy harvesting device may be provided with a plurality of sensors 7.

The wireless communication device 8 is arranged inside the housing case 1. The wireless communication device 8 is a wireless transmission device that transmits sensing data of the sensor 7 by radio. The wireless communication device 8 may be a wireless transmission/reception device that can receive data by radio.

The radio transmittance portion 9 is provided on at least a part of the housing case 1 for a radio wave to be transmissive. In the example in FIG. 6, the radio transmittance portion 9 is formed of a radio transmittance material through which the radio wave is transmissive. An example of the radio transmittance material includes a resin, glass and the like. The radio wave output from the wireless communication device 8 is transmitted to an exterior of the housing case 1 through the radio transmittance portion 9. Therefore, the radio transmittance portion 9 is preferably provided near an antenna of the wireless communication device 8.

It should be noted that in the example in FIG. 6, the radio transmittance portion 9 is provided on the upper surface of the housing case 1, but may be provided on the lateral surface thereof. In addition, the radio transmittance portion 9 may include one or a plurality of radio transmittance portions.

The wire 54 is a power wire that connects the power circuit 3 and the sensor 7. The output power of the power circuit 3 is supplied to the sensor 7 through the wire 54. The sensor 7 is driven by electric power supplied from the power circuit 3.

The wire 55 is a power wire that connects the power circuit 3 and the wireless communication device 8. The output power of the power circuit 3 is supplied to the wireless communication device 8 through the wire 55. The wireless communication device 8 is driven by electric power supplied from the power circuit 3.

The wire 56 is a signal line that connects the sensor 7 and the wireless communication device 8. The sensing data of the sensor 7 is input to the wireless communication device 8 through the wire 56. The wireless communication device 8 transmits the sensing data input from the sensor 7 by radio.

With the configuration as described above, the energy harvesting device, the sensor 7 and the wireless communication device 8 can be integrally configured.

In addition, since the sensor 7 and the wireless communication device 8 are arranged inside the housing case 1, it is not necessary to dispose the power wire and the signal line outside the housing case 1. Therefore, as compared to a case of connecting the energy harvesting device and the external device, a degree of freedom in the installation of the sensor 7 and the wireless communication device 8 can be more improved.

Further, in the energy harvesting device in FIG. 6, the radio transmittance portion 9 is configured by the radio transmittance material. Therefore, the inside of the housing case 1 is sealed, thus making it possible to improve the waterproof properties of the energy harvesting device.

FIG. 7 is a diagram showing another example of the energy harvesting device according to the present embodiment. In the energy harvesting device in FIG. 7, the sensor 7 is arranged outside the housing case 1. Therefore, a wire hole 15 for the passing of the wires 54, 55 is provided in the housing case 1. The other configuration is identical to that in FIG. 6.

With the configuration as described above, the energy harvesting device and the wireless communication device 8 can be integrally configured. In addition, since the sensor 7 is arranged outside the housing case 1, the sensor 7 can sense an environment outside the housing case 1.

It should be noted that a wire hole for the passing of the wire 54 and a wire hole for the passing of the wire 56 may be provided individually. Further, the sensor 7 may be arranged inside the housing case 1 and the wireless communication device 8 may be arranged outside the housing case 1.

FIG. 8 is a diagram showing a further other example of the energy harvesting device according to the present embodiment. The energy harvesting device in FIG. 8 is provided with a vent 10 instead of the radio transmittance portion 9. The vent 10 is a through hole provided on the upper surface of the housing case 1, and acts as the radio transmittance portion 9 in FIG. 6. That is, the radio wave output from the wireless communication device 8 is transmitted to an exterior of the housing case 1 through the vent 10. The other configuration is identical to that in FIG. 6.

In the energy harvesting device in FIG. 8, the inside of the housing case 1 is not sealed and is ventilated through the radio transmittance portion 9 (vent). Thereby, since air inside the housing case 1 heated by the thermoelectric generation element 2 is discharged, the heat release efficiency of the housing case 1 improves, thus making it possible to improve the cooling effect of the upper surface of the thermoelectric generation element 2 by the housing case 1.

It should be noted that the vent may include one or a plurality of vents. As shown in FIG. 8, ventilation characteristics of the housing case 1 are improved by providing the plurality of vents, thus making it possible to further improve the cooling effect of the upper surface of the thermoelectric generation element 2 by the housing case 1.

In addition, in the example in FIG. 8, the vents are provided on the upper surface of the housing case 1, but may be provided on the lateral surface or on both of the upper surface and the lateral surface of the housing case 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An energy harvesting device, comprising:
a housing case; and
a thermoelectric generation element arranged to contact with an outer surface of the housing case.

2. The energy harvesting device according to claim 1, comprising:
a power circuit arranged inside the housing case and into which output power of the thermoelectric generation element is input.

3. The energy harvesting device according to claim 1, wherein the housing case is formed of metal.

4. The energy harvesting device according to claim 1, wherein the housing case includes at least one wire hole.

5. The energy harvesting device according to claim 1, wherein the housing case includes a heat release fin on at least a part of the outer surface.

6. The energy harvesting device according to claim 2, comprising:
a piezo element arranged inside the housing case, wherein
output power of the piezo element is input into the power circuit.

7. The energy harvesting device according to claim 6, wherein the piezo element is fixed at one end thereof to the housing case.

8. The energy harvesting device according to claim 2, comprising:
a wireless communication device arranged inside the housing case and to which electric power is supplied from the power circuit.

9. The energy harvesting device according to claim 2, comprising:
a sensor arranged inside the housing case and to which electric power is supplied from the power circuit.

10. The energy harvesting device according to claim 1, wherein the housing case has a radio transmittance portion through which a radio wave is transmissive.

11. The energy harvesting device according to claim 10, wherein the radio transmittance portion is formed of a radio transmittance material through which a radio wave is transmissive.

12. The energy harvesting device according to claim 1, wherein the housing case has a vent.
